(19) United States
(12) Patent Application Publication
(10) Pub. No.: US 2017/0256661 A1
(43) Pub. Date: Sep. 7, 2017

(54) METHOD OF MANUFACTURING PHOTOVOLTAIC PANELS WITH VARIOUS GEOMETRICAL SHAPES

(71) Applicant: SolarCity Corporation, San Mateo, CA (US)

(72) Inventor: Zheng Xu, Pleasanton, CA (US)

(73) Assignee: SolarCity Corporation, San Mateo, CA (US)

(21) Appl. No.: 15/059,148

(22) Filed: Mar. 2, 2016

(51) Int. Cl. H01L 31/0475; H01L 31/20; H01L 31/0376; H01L 31/05; H01L 31/074; H01L 31/0352

(52) U.S. Cl. CPC H01L 31/0475; H01L 31/074; H01L 31/035209; H01L 31/03762; H01L 31/0508; H01L 31/0512; H01L 31/202

(57) ABSTRACT

One embodiment of the present invention provides a photovoltaic module. The photovoltaic module includes a front-side cover, a back-side cover, and a plurality of angled photovoltaic strings situated between the front- and back-side covers. A respective angled photovoltaic string includes a plurality of photovoltaic cells coupled in series with an offset. The angled photovoltaic strings are couple in parallel and form a geometrical shape of the photovoltaic panel with at least one vertex having an oblique angle.

### CROSS-REFERENCE TO OTHER APPLICATIONS

This is related to U.S. patent application Ser. No. 14/563,867, Attorney Docket Number P67-3NUS, entitled “HIGH EFFICIENCY SOLAR PANEL,” filed Dec. 8, 2014; and U.S. patent application Ser. No. 14/510,008, Attorney Docket No. P67-2NUS, entitled “MODULE FABRICATION OF SOLAR CELLS WITH LOW RESISTIVITY ELECTRODES,” filed 8 Oct. 2014, the disclosures of which are incorporated herein by reference in their entirety for all purposes.

This is also related to U.S. patent application Ser. No. 12/945,792, Attorney Docket No. P53-1NUS, entitled “SOLAR CELL WITH OXIDE TUNNELING JUNCTIONS,” filed 12 Nov. 2010; U.S. patent application Ser. No. 13/048,804, Attorney Docket No. P54-1NUS, entitled “SOLAR CELL WITH A SHADE-FREE FRONT ELECTRODE,” filed 15 Mar. 2011; U.S. patent application Ser. No. 14/985,223, Attorney Docket No. P128-1NUS, entitled “ADVANCED DESIGN OF METALLIC GRID IN PHOTOVOLTAIC STRUCTURES,” filed 30 Dec. 2015; and U.S. patent application Ser. No. 14/857,653, Attorney Docket No. P119-1NUS, entitled “PHOTOVOLTAIC CELLS WITH ELECTRODES ADAPTED TO HOUSE CONDUCTIVE PASTE,” filed Sep. 17, 2015; the disclosures of which are incorporated herein by reference in their entirety for all purposes.

### FIELD OF THE INVENTION

This disclosure is related to solar panel design including fabrication of solar panels having different geometrical shapes.

### DEFINITIONS

A “photovoltaic structure,” refers to a device capable of converting light to electricity. A photovoltaic structure can include a number of semiconductors or other types of materials.

A “solar cell” or “cell” is a type of photovoltaic (PV) structure capable of converting light into electricity. A solar cell may have various sizes and shapes, and may be created from a variety of materials. A solar cell may be a PV structure fabricated on a semiconductor (e.g., silicon) wafer or substrate, or one or more thin films fabricated on a substrate (e.g., glass, plastic, metal, or any other material capable of supporting the photovoltaic structure).

A “finger line,” “finger electrode,” “finger strip,” or “finger” refers to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a PV structure for aggregating current collected by two or more finger lines. A busbar is usually wider than a finger line, and can deposited or otherwise positioned anywhere on or within the photovoltaic structure. A single photovoltaic structure may have one or more busbars.

A “metal grid,” “metallic gird,” or “grid” is a collection of finger lines and one or more busbars. The metal grid fabrication process typically includes depositing or otherwise positioning a layer of metallic material on the photovoltaic structure using various techniques.

A “solar cell strip,” “photovoltaic strip,” or “strip” is a portion or segment of a PV structure, such as a solar cell. A PV structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

### BACKGROUND

The negative environmental impact of fossil fuels and their rising cost have resulted in need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi-junction structure includes multiple single-junction structures of different bandgaps stacked on top of one another.

In a solar cell, light is absorbed near the p-n junction generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit. High efficiency solar cells are essential in reducing cost to produce solar energies.

In practice, multiple individual solar cells are interconnected, assembled, and packaged together to form a solar panel, which can be mounted onto a supporting structure. Multiple solar panels can then be linked together to form a solar system that generates solar power. Depending on its scale, such a solar system can be a residential roof-top system, a commercial roof-top system, or a ground-mount utility-scale system.

Note that in such systems, in addition to the energy conversion efficiency of each individual cell, the ways cells are electrically interconnected within a solar panel also determine the total amount of energy that can be extracted from each panel. Due to the conventional solar cell shape and inter-cell connections, the geometrical shapes of manufactured solar panels are limited to square or rectangles, which can be limiting when being installed as a residential roof-top system, a commercial roof-top system, or a ground-mount utility-scale system. For example, conventional solar panels fail to thoroughly cover an installation area that is not a perfect rectangular or square shaped. Therefore, it is desirable to manufacture solar panels with various geometrical shapes to more effectively produce solar energies via improved solar system installations.

### SUMMARY

One embodiment of the present invention provides a photovoltaic panel. The photovoltaic panel includes several photovoltaic cells arranged into multiple subsets, where some of the subsets include a number of photovoltaic cells arranged with an offset forming a geometrical shape with one or more oblique-angled vertices. The photovoltaic cells in a subset are electrically coupled in series, and the subsets of photovoltaic cells are electrically coupled in parallel. The number of photovoltaic cells in a subset is sufficiently large such that the output voltage of the photovoltaic panel is substantially the same as an output voltage of a conventional photovoltaic panel with all of its substantially square shaped photovoltaic cells coupled in series.

In some embodiments, the photovoltaic cell in a subset is obtained by dividing a substantially square shaped photovoltaic cell.

In some embodiments, the photovoltaic cell in a subset is obtained by dividing a substantially square shaped photovoltaic cell into three rectangular pieces.

In some embodiments, the formed geometrical shape of the photovoltaic panel can be a triangle, parallelogram, or trapezoid.

In some embodiments, a portion of the formed geometrical shape of the photovoltaic panel is curved.

In some embodiments, a respective photovoltaic cell is a double-sided tunneling heterojunction photovoltaic cell, which includes a base layer, first and second quantum tunneling barrier (QTB) layers deposited on both surfaces of the base layer, an amorphous silicon emitter layer, and an amorphous silicon surface field layer. In addition, the photovoltaic cell can absorb light from both surfaces.

In some embodiments, a respective photovoltaic cell includes a first metal grid on a first side and a second metal grid on a second side, where the first metal grid includes a first edge busbar located at an edge on the first side and the second metal grid comprises a second edge busbar located at an opposite edge on the second side of the photovoltaic cell.

In some embodiments, the first metal grid and the second metal grid include an electroplated Cu layer.

In some embodiments, two adjacent photovoltaic cells in a subset are positioned so that a first edge busbar of one photovoltaic cell is in direct contact with a second busbar of the other photovoltaic cell, thereby facilitating a serial connection between the two adjacent photovoltaic cells and eliminating uncovered space between the two adjacent solace cells.

In some embodiments, two adjacent photovoltaic cells in a subset are positioned with an offset so that a portion of a first edge busbar of one photovoltaic cell is in direct contact with a second busbar of the other photovoltaic cell, thereby arranging the two adjacent photovoltaic cells with an offset.

In some embodiments, the photovoltaic cells in a respective subset form a U-shaped string.

In some embodiments, the photovoltaic cells in the respective subset are physically coupled.

In some embodiments, a photovoltaic panel fabrication process includes obtaining substantially square shaped photovoltaic cells, dividing each of the substantially square shaped photovoltaic cells into multiple smaller photovoltaic cells, electrically coupling a plurality of photovoltaic strips with an offset in series to form an angled string, electrically coupling multiple angled strings to form a geometrical shape of the photovoltaic panel having at least one vertex with an oblique angle, and applying a frond-side cover and a back side cover over the multiple electrically coupled angled strings.

In some embodiments, the photovoltaic cell includes a transparent conducting oxide (TCO) layer, and the metal adhesive layer is in direct contact with the TCO layer.

In some embodiments, the electroplated metal layers include one or more of a Cu layer, an Ag layer, and a Sn layer.

In some embodiments, the metallic grid further includes a metal seed layer between the electroplated metal layer and photovoltaic structure.

In some embodiments, the metal seed layer is formed using a physical vapor deposition (PVD) technique, including evaporation or sputtering deposition.

In some embodiments, the photovoltaic cell includes a base layer, and an emitter layer above the base layer. The emitter layer includes regions diffused with dopants located within the base layer, a poly silicon layer diffused with dopants situated above the base layer, or a doped amorphous silicon (a-Si) layer above the base layer.

In some embodiments, a back junction photovoltaic cell is provided, which includes a base layer, a quantum-tunneling-barrier (QTB) layer situated below the base layer facing away from incident light, an emitter layer situated below the QTB layer, a front surface field (FSF) layer situated above the base layer, a front-side electrode situated above the FSF layer, and a back-side electrode situated below the emitter layer.

### BRIEF DESCRIPTION OF THE FIGURES

FIG. 1 shows a detailed view of an exemplary double-sided tunneling heterojunction photovoltaic cell.

FIG. 2A shows a detailed view of an exemplary electrode grid of a conventional photovoltaic cell.

FIG. 2B shows a cross-sectional view of an exemplary bifacial photovoltaic cell with a single center busbar per surface.

FIG. 3A shows a detailed view of the front surface of an exemplary bifacial photovoltaic cell with a single edge busbar.

FIG. 3B shows a detailed view of the back surface of an exemplary bifacial photovoltaic cell with a single edge busbar.

FIG. 3C shows a cross-sectional view of an exemplary bifacial photovoltaic cell with a single edge busbar per surface.

FIG. 4A shows a detailed view of an exemplary serial connection between two adjacent photovoltaic cells with a single edge busbar per surface.

FIG. 4B shows the side-view of an exemplary string of adjacent edge-overlapped photovoltaic cells.

FIG. 4C shows a top view of an exemplary photovoltaic panel that includes a plurality of photovoltaic cells connected in series each having one busbar.

FIG. 5 shows a simplified equivalent circuit of a photovoltaic panel with serially connected photovoltaic cells.

FIG. 6 shows a simplified equivalent circuit of a photovoltaic panel with parallelly connected photovoltaic cells.

FIG. 7 shows a detailed view of an exemplary photovoltaic panel configuration.

FIG. 8 shows a detailed view of an exemplary photovoltaic cell string with each photovoltaic cell being divided into multiple photovoltaic strips.

FIG. 9 shows a detailed view of an exemplary photovoltaic panel having multiple photovoltaic strings connected in parallel with each photovoltaic string includes photovoltaic strips.

FIG. 10A shows a detailed view of an exemplary metallic grid pattern on the front surface of a photovoltaic cell.

FIG. 10B shows a detailed view of an exemplary metallic grid pattern on the back surface of a photovoltaic cell.

FIG. 11 shows a detailed view of an exemplary serial connection between two adjacent photovoltaic cells with an offset each with a single edge busbar per surface, in accordance with an embodiment of the present invention.

FIG. 12 shows a top view of an exemplary serial connection between adjacent photovoltaic cells with an offset each with a single edge busbar per surface, in accordance with an embodiment of the present invention.

FIG. 13 shows a top view of an exemplary solar cell string that includes two rows of smaller cells, in accordance with an embodiment of the present invention.

FIG. 14 shows a top view of an exemplary photovoltaic panel in shape of a triangle that includes a plurality of photovoltaic cells connected in series with an offset each having one busbar, in accordance with an embodiment of the present invention.

FIG. 15 shows a top view of an exemplary photovoltaic panel in shape of a right triangle that includes a plurality of photovoltaic cells connected in series with an offset each having one busbar, in accordance with an embodiment of the present invention.

FIG. 16 shows a top view of an exemplary photovoltaic panel in shape of a trapezoid that includes a plurality of photovoltaic cells connected in series with an offset each having one busbar, in accordance with an embodiment of the present invention.

FIG. 17 shows a top view of an exemplary photovoltaic panel in shape of a parallelogram that includes a plurality of photovoltaic cells connected in series with an offset each having one busbar, in accordance with an embodiment of the present invention.

FIGS. 18A-G show an exemplary process of fabricating a photovoltaic panel, in accordance with an embodiment of the present invention.

FIG. 19 shows a flow chart showing the process of fabricating a photovoltaic panel, in accordance with an embodiment of the present invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

Embodiments of the present invention provide solar panels with various geometrical shapes. To maximize the surface area of an installation site that is covered by solar panels, the present inventive solar panels in various geometrical shapes can be used. Such solar panels can include angled solar cell strings having multiple solar strips. These angled solar strings are created by arranging solar strips with an offset. Moreover, to create the solar strips of the angled strings, each conventional square-shaped wafer, after the device structure is fabricated, is divided into a number of cut cells, which can be rectangular-shaped strips and can be serially coupled with an offset to form solar panels with various geometric shapes.

During the solar cell fabrication process, front and back metal grid patterns are specially designed to facilitate the division of a square-shaped wafer into cut cells. More specifically, spaces are reserved for the laser-based scribe-and-cleave operation. To reduce shading and to increase the packing factor, in some embodiments, the cells are connected in a shingled pattern.

Bifacial Tunneling Junction Photovoltaic cells

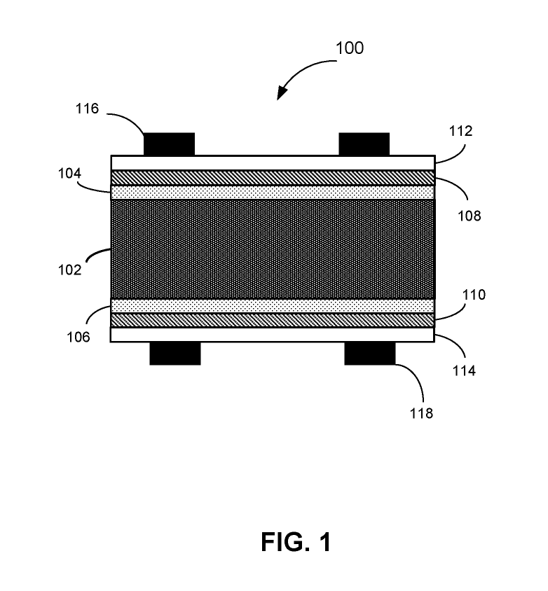

FIG. 1 shows an exemplary double-sided tunneling junction photovoltaic structure. Double-sided tunneling junction photovoltaic structure 100 includes substrate 102, quantum tunneling barrier (QTB) layers 104 and 106 covering opposite surfaces of substrate 102 and passivating the surface-defect states, a front-side doped a-Si layer forming front emitter 108, a back-side doped a-Si layer forming BSF layer 110, front transparent conducting oxide (TCO) layer 112, back TCO layer 114, front metal grid 116, and back metal grid 118. Note that it is also possible to have the emitter layer at the backside and a front surface field (FSF) layer at the front side of the PV structure. Details, including fabrication methods, about double-sided tunneling junction photovoltaic structure100 can be found in U.S. patent application Ser. No. 12/945,792 (Attorney Docket No. P53-1NUS), entitled “SOLAR CELL WITH OXIDE TUNNELING JUNCTIONS,” by inventors Jiunn Benjamin Heng, Chentao Yu, Zheng Xu, and Jianming Fu, filed 12 Nov. 2010, the disclosure of which is incorporated herein by reference in its entirety herein.

As one can see from FIG. 1, the double-sided tunneling junction PV structure 100 ensures that it can be bifacial given that the backside is exposed to light. In photovoltaic structures, the metallic contacts, such as front and back metallic grids 116 and 118, can collect the current generated by the PV structure. In general, a metallic grid can include two types of metallic lines, including busbars and fingers. More specifically, busbars can be wider metallic lines that are connected directly to external leads (such as metal tabs), while fingers can be finer areas of metalization collecting current for delivery to the busbars.

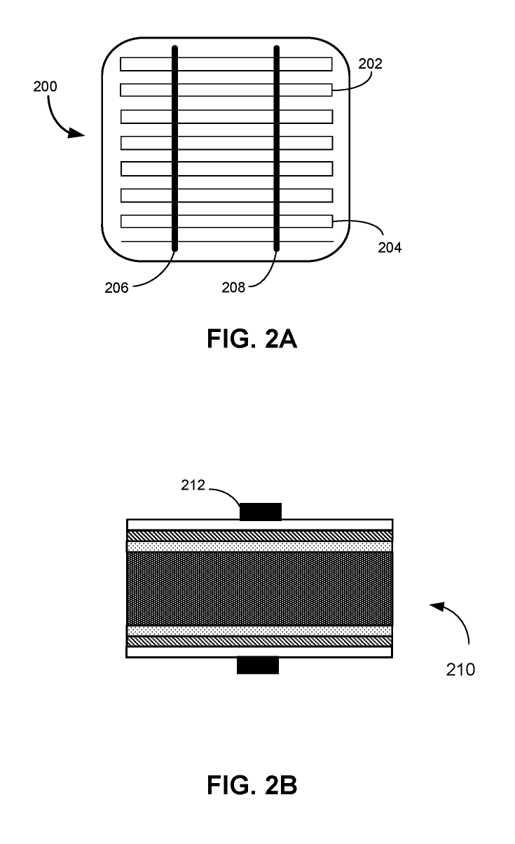

One factor in the metallic grid design is the balance between the increased resistive losses associated with a widely spaced grid and the increased reflection and shading effect caused by a high fraction of metallic coverage of the surface. In conventional PV structures, to prevent power loss due to series resistance of the finger lines, at least two busbars are placed on the surface of the photovoltaic cell to collect current from the fingers, as shown in FIG. 2A. For standardized PV structures, typically two or more busbars at each surface may be needed depending on the resistivity of the electrode materials. Note that in FIG. 2A a surface (which can be the front or back surface) of photovoltaic structure 200 includes a plurality of parallel finger lines, such as finger lines 202 and 204; and two busbars 206 and 208 placed substantially perpendicular to the finger lines. The busbars can be placed in such a way as to ensure that the distance (and hence the resistance) from any point on a finger to a busbar is small enough to minimize power loss. However, these two busbars and the metallic ribbons that are later soldered onto these busbars can create a significant amount of shading, which degrades the photovoltaic structure performance.

In some embodiments, the front and back metallic grids, such as the finger lines, can include electroplated Cu lines. By using an electroplating or electroless plating technique, one can obtain Cu grid lines with a resistivity of equal to or less than 5×10⁻⁶ Ω·cm. In addition, a metal seed layer (such as Ti) can be deposited directly on the TCO layer using, for example, a physical vapor deposition (PVD) process. This seed layer ensures excellent ohmic contact with the TCO layer as well as a strong physical bond with the photovoltaic cell structure. Subsequently, the Cu grid can be electroplated onto the seed layer. This two-layer (seed layer and electroplated Cu layer) ensures excellent ohmic contact quality, physical strength, low cost, and facilitates large-scale manufacturing. Details about an electroplated Cu grid can be found in U.S. patent application Ser. No. 12/835,670 (Attorney Docket No. P52-1NUS), entitled “Solar Cell with Metal Grid Fabricated by Electroplating,” by inventors Jianming Fu, Zheng Xu, Chentao Yu, and Jiunn Benjamin Heng, filed 13 Jul. 2010; and U.S. patent application Ser. No. 13/220,532 (Attorney Docket No. P59-1NUS), entitled “SOLAR CELL WITH ELECTROPLATED METAL GRID,” by inventors Jianming Fu, Jiunn Benjamin Heng, Zheng Xu, and Chentao Yu, filed 29 Aug. 2011, the disclosures of which are incorporated herein by reference in their entirety herein.

The reduced resistance of the Cu fingers makes it possible to have a metallic grid design that maximizes the overall efficiency of a photovoltaic structure by reducing the number of busbars on its surface. The power loss caused by the increased distance from the fingers to the busbar can be balanced by the reduced shading.

FIG. 2B shows a cross-sectional view of the bifacial photovoltaic structure with a single center busbar per surface. The semiconductor multilayer structure shown in FIG. 2B can be similar to the one shown in FIG. 1. Note that the finger lines are not shown in FIG. 2B because the cut plane cuts between two finger lines. In the example shown in FIG. 2B, busbar 212 runs in and out of the paper, and the finger lines run from left to right. As discussed previously, because there is only one busbar at each surface, the distances from the edges of the fingers to the busbar are longer. However, the elimination of one busbar reduces shading, which not only compensates for the power loss caused by the increased finger-to-busbar distance, but also provides additional power gain. For a standard sized photovoltaic cell, replacing two busbars with a single busbar in the center of the cell can produce an approximately 1.8% power gain.

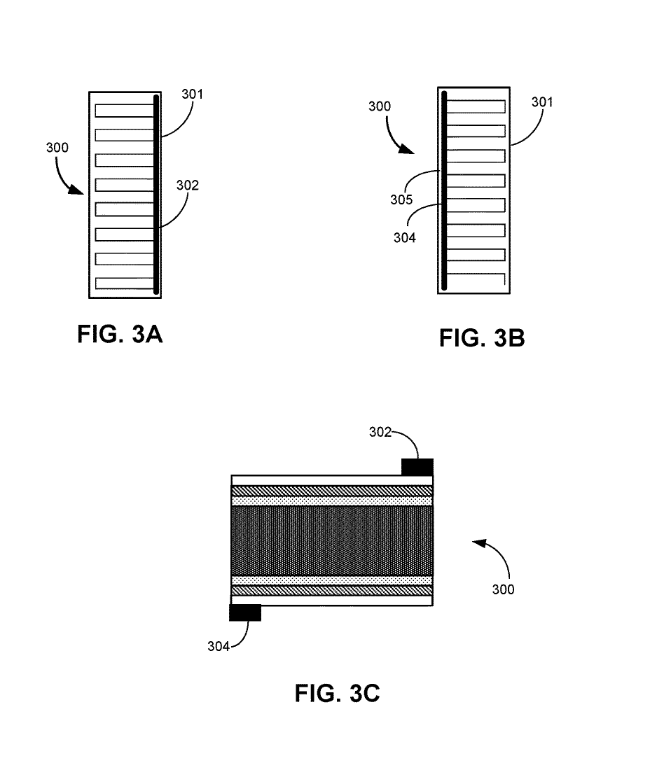

FIG. 3A shows an exemplary bifacial photovoltaic structure. In FIG. 3A, the front surface of photovoltaic structure 300 includes a number of horizontal finger lines and a vertical single busbar 302, which is placed at the right edge of PV structure 300. More specifically, busbar 302 is in contact with the rightmost edge of all the finger lines, and collects current from all the finger lines. FIG. 3B shows the back surface of an exemplary bifacial PV structure. In FIG. 3B, the back surface of PV structure 300 includes a number of horizontal finger lines and a vertical single busbar 304, which is placed at the left edge of PV structure 300. Similar to busbar 302, single busbar 304 is in contact with the leftmost edge of all the finger lines.

FIG. 3C shows a cross-sectional view of the bifacial photovoltaic cell with a single edge busbar per surface. The semiconductor multilayer structure shown in FIG. 3C can be similar to the one shown in FIG. 2B. Like FIG. 2B, in FIG. 3C, the finger lines (not shown) run from left to right, and the busbars run in and out of the paper. From FIGS. 3A-3C, the busbars on the front and the back surfaces of the bifacial PV structures are placed at the opposite edges of the PV structure. This configuration can further improve power gain because the busbar-induced shading now occurs at locations that were less effective in energy production. In general, the edge-busbar configuration can provide at least an approximate 2.1% power gain.

Note that the single busbar per surface configurations (either the center busbar or the edge busbar) not only can provide power gain, but also can reduce fabrication cost, because less metal will be needed for busing ribbons. Moreover, the metal grid on the front sun-facing surface can include parallel metal lines (such as fingers), each having a cross-section with a curved parameter to ensure that incident sunlight on these metal lines is reflected onto the front surface of the photovoltaic cell, thus further reducing shading. Such a shade-free front electrode can be achieved by electroplating Ag- or Sn-coated Cu using a well-controlled, cost-effective patterning scheme.

It is also possible to reduce the power-loss effect caused by the increased distance from the finger edges to the busbars by increasing the aspect ratio of the finger lines. For example, with gridlines with an aspect ratio of 0.5, the power loss could degrade from 3.6% to 7.5% as the gridline length increases from 30 mm to 100 mm. However, with a higher aspect ratio, such as 1.5, the power loss could degrade from 3.3% to 4.9% for the same increase of gridline length. In other words, using high-aspect ratio gridlines can further improve performance. Such high-aspect ratio gridlines can be achieved using an electroplating technique. Details about the shade-free electrodes with high-aspect ratio can be found in U.S. patent application Ser. No. 13/048,804 (Attorney Docket No. P54-1NUS), entitled “SOLAR CELL WITH A SHADE-FREE FRONT ELECTRODE,” by inventors Zheng Xu, Jianming Fu, Jiunn Benjamin Heng, and Chentao Yu, filed 15 Mar. 2011, the disclosure of which is incorporated herein by reference in its entirety herein.

### Bifacial Photovoltaic Panels Based on Cascaded Strips

Multiple photovoltaic cells with a single busbar (either at the cell center or the cell edge) per surface can be assembled to form a photovoltaic module or panel via a typical panel fabrication process with minor modifications. Based on the locations of the busbars, different modifications to the stringing/tabbing process are needed. In conventional photovoltaic module fabrications, the double-busbar photovoltaic cells are strung together using stringing ribbon(s) (also called tabbing ribbon(s)), which are soldered onto the busbars. More specifically, the stringing ribbons weave from the front surface of one cell to the back surface of the adjacent cell to connect the cells in series. For the single busbar in the cell center configuration, multiple cells with single busbar can be strung or stacked with one another to form a string.

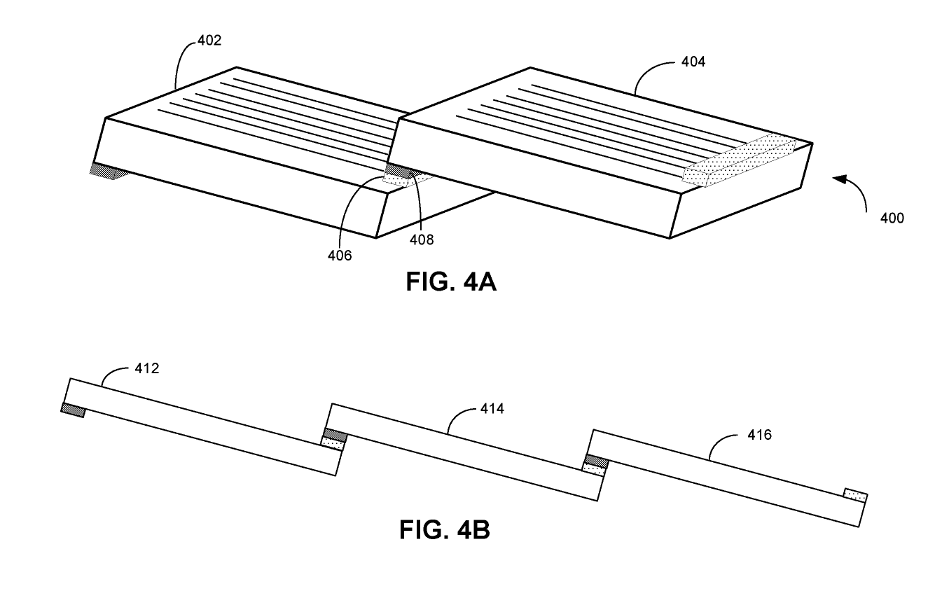

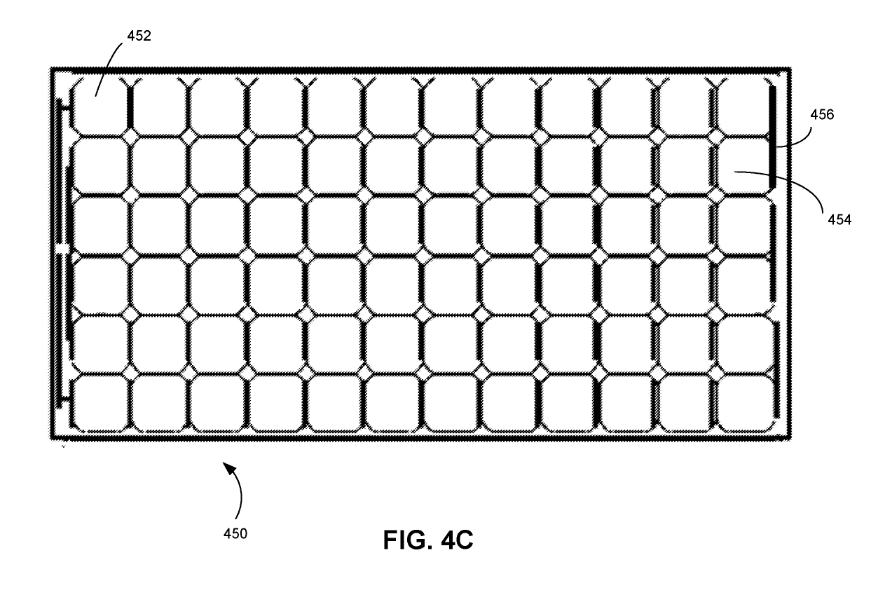

In addition to using a single tab to connect adjacent PV cells in series, the serial connection between adjacent photovoltaic cells is achieved by partially overlapping the adjacent PV cells, thus resulting in the direct contact of the corresponding edge busbars. FIG. 4A shows the serial connection between two adjacent PV cells with a single edge busbar per surface. In FIG. 4A, cell 402 and PV cell 404 are coupled to each other via edge busbar 406 located at the top surface of cell 402 and edge busbar 408 located the bottom surface of PV cell 404. More specifically, the bottom surface of cell 404 partially overlaps with the top surface of photovoltaic cell 402 at the edge in such a way that bottom edge busbar 408 is placed on top of and in direct contact with top edge busbar 406 so that the edge busbars that are in direct contact with each other can be soldered and secured.

FIG. 4B shows the side-view of a string of adjacent edge-overlapped PV cells. In FIG. 4B, PV cell 412 partially overlaps adjacent cell 414, which also partially overlaps (on its opposite end) photovoltaic cell 416. Such a string of photovoltaic cells forms a pattern that is similar to roof shingles. The overlapping should be kept to a minimum to minimize shading caused by the overlapping. Sometimes the single busbars (both at the top and the bottom surface) are placed at the very edge of the PV cell (as shown in FIG. 4B), thus minimizing the overlapping. The same shingle pattern can extend along all photovoltaic cells in a row. To ensure that PV cells in two adjacent rows are connected in series, the two adjacent rows need to have opposite shingle patterns, such as right-side on top for one row and left-side on top for the adjacent row. Moreover, a metal tab can be used to serially connect the end cells at the two adjacent rows. Detailed descriptions of serially connecting solar cells in a shingled pattern can be found in U.S. patent application Ser. No. 14/510,008 (Attorney Docket No. P67-2NUS), entitled “MODULE FABRICATION OF SOLAR CELLS WITH LOW RESISTIVITY ELECTRODES,” by inventors Jiunn Benjamin Heng, Jianming Fu, Zheng Xu, and Bobby Yang, filed 8 Oct. 2014, the disclosure of which is incorporated herein by reference in its entirety herein.

Note that although the examples above illustrate adjacent solar cells being physically coupled with direct contact in a “shingling” configuration, in some embodiments of the present invention, the adjacent solar cells can also be coupled electrically in series using conductive materials without being in direct contact with one another. FIG. 4C shows photovoltaic panel 450 that includes a plurality of shingled pattern photovoltaic cells. In FIG. 4C, photovoltaic panel 450 includes an array (with 6 rows and 12 cells in a row) of photovoltaic cells. The serial connection is made by the overlapped edge busbars. As a result, when viewing from the top, no busbar can be seen on each PV cell. Therefore, this configuration can also be referred to as the “no-busbar” configuration. In FIG. 4C, at the right end of the rows, an extra wide metal tab 456 couples together the top edge busbar of the end photovoltaic cell of row 452 to the bottom edge busbar of the end cell of row 454. At the left end of the rows, lead wires can be soldered onto the top and bottom edge busbars of the end photovoltaic cells, forming the output electrode of each string with other strings.

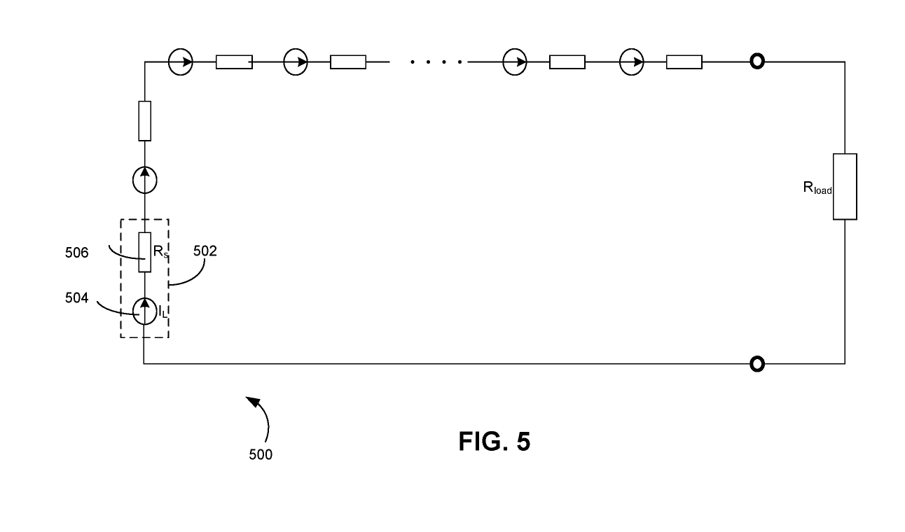

FIG. 5 presents a diagram illustrating a simplified equivalent circuit of a photovoltaic panel with serially connected photovoltaic cells. In FIG. 5, each photovoltaic cell is represented by a current source with an internal resistance. For example, a photovoltaic cell 502 is represented by a current source 504 coupled in series with a resistor 506. When a photovoltaic panel includes serially connected photovoltaic cells, as shown in FIG. 5, the output power of the entire panel is determined by the total generated current (I_{L}_{_}ₜₒₜₐₗ) and the sum of total internal resistance (Rₛ_{_}ₜₒₜₐₗ) and external resistance (i.e., the load resistance, R_{load}). For example, if all photovoltaic cells are identical and receive the same amount of light, for n serially connected photovoltaic cells, I_{L}_{_}ₜₒₜₐₗ=I_{L} and Rₛ_{_}ₜₒₜₐₗ=nRₛ, and the total power generated by the entire circuit can be calculated as Pₒᵤₜ=I_{L}²×(Rₛ_{_}ₜₒₜₐₗ+R_{load}). Assuming that the load resistance R_{load} is adjusted by a maximum power point tracking (MPPT) circuit such that the total resistance for the entire circuit (Rₛ_{_}ₜₒₜₐₗ+R_{load}) allows the entire panel to operate at the maximum power point (which means at a fixed I_{L}_{_}ₜₒₜₐₗ), the amount of power extracted to the external load depends on the total internal resistance Rₛ_{_}ₜₒₜₐₗ. In other words, a portion of the generated power is consumed by the serial internal resistance in the photovoltaic cells themselves: P_{R}=I_{L}²×nR_{S}. That means the less the total internal resistance the entire panel has, the less power is consumed by the photovoltaic cells themselves, and the more power is extracted to the external load.

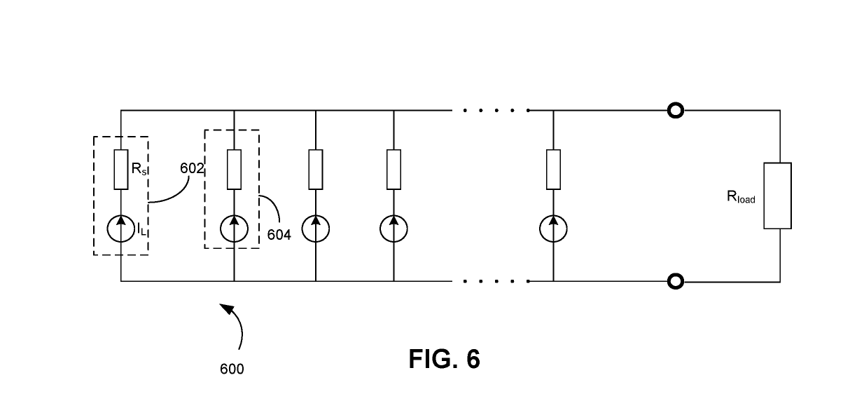

One way to reduce the power consumed by the photovoltaic cells is to reduce the total internal resistance. Various approaches can be used to reduce the series resistance of the electrodes at the cell level. On the panel level, one effective way to reduce the total series resistance is to connect a number of cells in parallel, instead of connecting all the cells within a panel in series. FIG. 6 presents a diagram illustrating a simplified equivalent circuit of a photovoltaic panel with parallelly connected photovoltaic cells, in accordance with one embodiment of the present invention. In the example illustrated in FIG. 6, all photovoltaic cells, such as photovoltaic cells 602 and 604, are connected in parallel. As a result, the total internal resistance of the photovoltaic panel is Rₛ_{_}ₜₒₜₐₗ=Rₛ/n , much smaller than the resistance of each individual photovoltaic cell. However, the output voltage V_{load} is now limited by the open circuit voltage of a single photovoltaic cell, which is difficult in a practical setting to drive load, although the output current can be n times the current generated by a single photovoltaic cell.

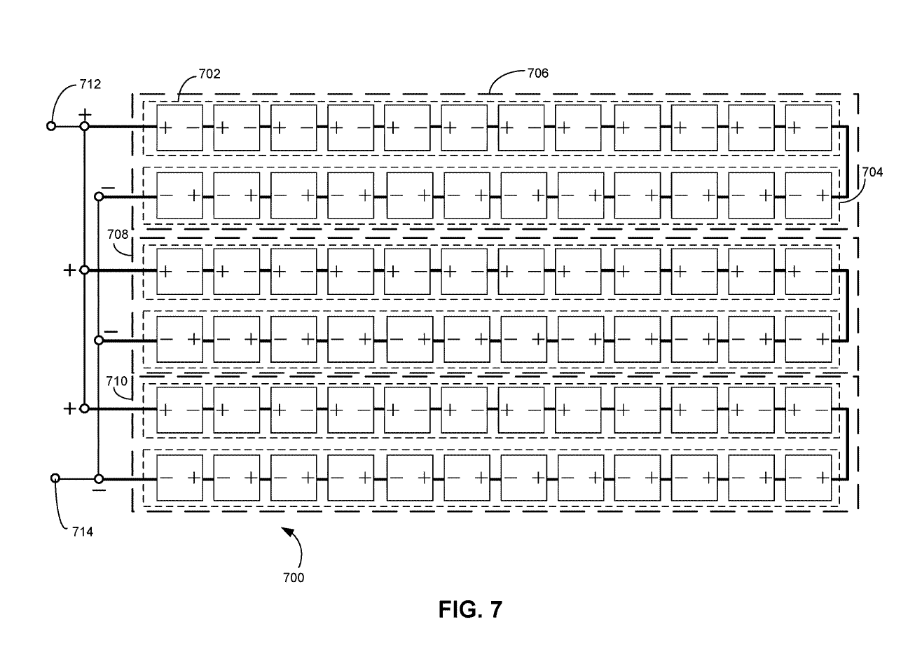

In order to attain an output voltage that is higher than that of the open circuit voltage of a single cell while reducing the total internal resistance for the panel, in some embodiments of the present invention, a subset of photovoltaic cells are connected into a string, and the multiple strings are connected in parallel. In the example shown FIG. 7, photovoltaic cells in top row 702 and second row 704 are connected in series to form a U-shaped string 706. Similarly, the photovoltaic cells in the middle two rows are also connected in series to form a U-shaped string 708, and the photovoltaic cells in the bottom two rows are connected in series as well to form a U-shaped string 710. The three U-shaped strings 706, 708, and 710 are then connected to each other in parallel. More specifically, the positive outputs of all three strings are coupled together to form the positive output 712 of photovoltaic panel 700, and the negative outputs of all strings are coupled together to form the negative output 714 of photovoltaic panel 700.

By serially connecting photovoltaic cells in subsets to form strings and then parallelly connecting the strings, one can reduce the serial resistance of the photovoltaic panel to a fraction of that of a conventional photovoltaic panel with all the cells connected in series. In the example shown in FIG. 7, the cells on a panel are divided into three strings (two rows in each string) and the three strings are parallelly connected, resulting in the total internal resistance of photovoltaic panel 700 being 1/9 of a conventional photovoltaic panel that has all of its 72 cells connected in series. The reduced total internal resistance decreases the amount of power consumed by the photovoltaic cells, and allows more power to be extracted to external loads.

Parallelly connecting the strings also means that the output voltage of the panel is now the same as the voltage across each string, which is a fraction of the output voltage of a photovoltaic panel with all cells connected in series. In the example shown in FIG. 7, the output voltage of panel 700 is ⅓ of a photovoltaic panel that has all of its 72 cells connected in series.

Because the output voltage of each string is determined by the voltage across each photovoltaic cell (which is often slightly less than V_{oc}) and the number of serially connected cells in the string, one can increase the string output voltage by including more cells in each string. However, simply adding more cells in each row will result in an enlarged panel size, which is often limited due to various mechanical factors. Note that the voltage across each cell is mostly determined by V_{oc}, which is independent of the cell size. Hence, it is possible to increase the output voltage of each string by dividing each standard sized (5- or 6-inch) photovoltaic cell into multiple serially connected photovoltaic strips. As a result, the output voltage of each string of photovoltaic cells is increased multiple times.

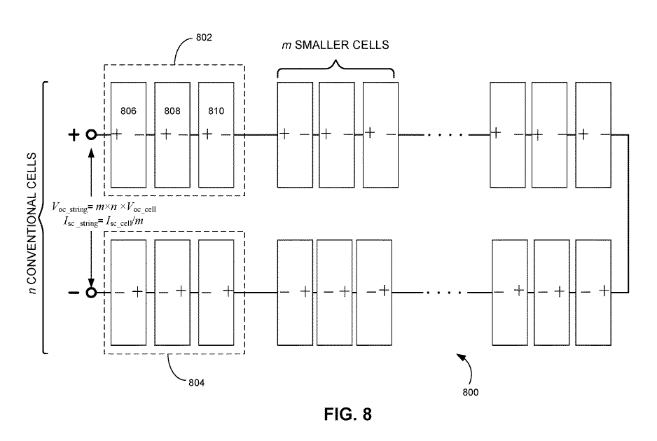

FIG. 8 shows a photovoltaic cell string with each photovoltaic cell being divided into multiple smaller cells, in accordance with an embodiment of the present invention. In the example illustrated in FIG. 8, a photovoltaic cell string 800 includes a number of photovoltaic strips. A conventional photovoltaic cell (such as the one represented by dotted line 802) is replaced by a number of serially connected smaller cells, such as cells 806, 808, and 810. For example, if the conventional photovoltaic cell is a 6-inch square cell, each strip can have a dimension of 2-inch by 6-inch, and a conventional 6-inch square cell is replaced by three 2-inch by 6-inch strips connected in series. Note that, as long as the layer structure of the photovoltaic strips remains the same as the conventional square-sized photovoltaic cell, the photovoltaic strips will have the same V_{oc} as that of the undivided photovoltaic cell. On the other hand, the current generated by each smaller cell is only a fraction of that of the original undivided cell due to its reduced size. Furthermore, the output current by photovoltaic cell string 800 is a fraction of the output current by a conventional photovoltaic cell string with undivided cells. The output voltage of the photovoltaic cell strings is now three times that of a photovoltaic string with undivided cells, thus making it possible to have parallelly connected strings without sacrificing the output voltage.

Now assuming that the open circuit voltage (V_{oc}) across a standard 6-inch photovoltaic cell is V_{oc}_{_}_{cell}, then the V_{oc} of each string is m×n×V_{oc}_{_}_{cell}, wherein m is the number of smaller cells as the result of dividing a conventional square shaped cell, and n is the number of conventional cells included in each string. On the other hand, assuming that the short circuit current (I_{sc}) for the standard 6-inch photovoltaic cell is I_{sc}_{_}_{cell}, then the I_{sc} of each string is I_{sc}_{_}_{cell}/m. Hence, when m such strings are connected in parallel in a new panel configuration, the V_{oc} for the entire panel will be the same as the V_{oc} for each string, and the I_{sc} for the entire panel will be the sum of the I_{sc} of all strings. More specifically, with such an arrangement, one can achieve: V_{oc}_{_}ₚₐₙₑₗ=m×n×V_{oc}_{_}_{cell} and I_{sc}_{_}ₚₐₙₑₗ=I_{sc}_{_}_{cell}. This means that the output voltage and current of this new photovoltaic panel will be comparable to the output voltage and current of a conventional photovoltaic panel of a similar size but with undivided photovoltaic cells all connected in series. The similar voltage and current outputs make this new panel compatible with other devices, such as inverters, that are used by a conventional photovoltaic panel with all its undivided cells connected in series. Although having similar current and voltage output, the new photovoltaic panel can extract more output power to external load because of the reduced total internal resistance.

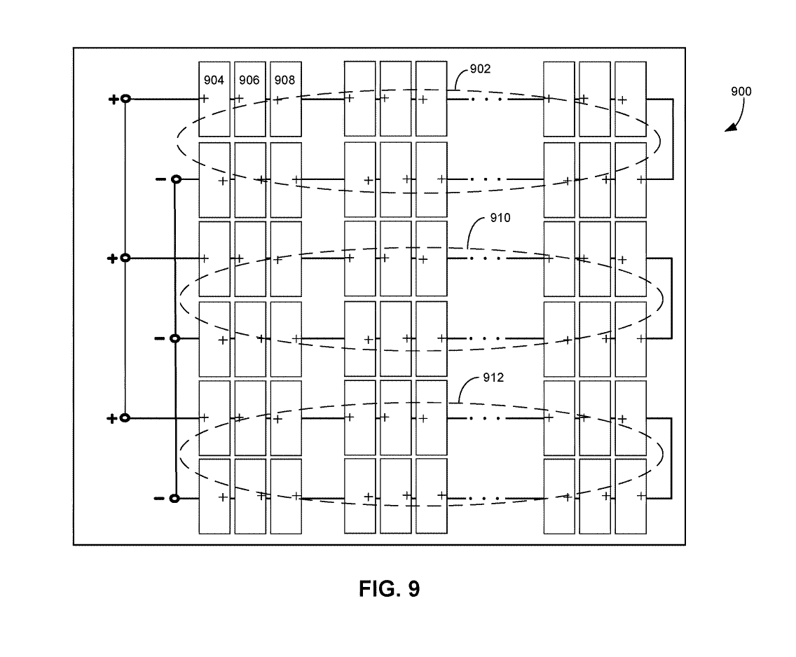

FIG. 9 presents a diagram illustrating an exemplary photovoltaic panel, in accordance with an embodiment of the present invention. In this example, photovoltaic panel 900 includes arrays of photovoltaic cells that are arranged in a repeated pattern, such as a matrix that includes a plurality of rows. In some embodiments, photovoltaic panel 900 can include six rows of inter-connected smaller cells, with each row including 36 smaller cells. Note that each smaller cell is approximately ⅓ of a 6-inch standardized photovoltaic cell. For example, smaller cells 904, 906, and 908 are evenly divided portions of a standard-sized cell. Solar panel 900 is configured in such a way that every two adjacent rows of smaller cells are connected in series, forming three U-shaped strings. In FIG. 9, the top two rows of smaller cells are connected in series to form a photovoltaic string 902, the middle two rows of smaller cells are connected in series to form a photovoltaic string 910, and the bottom two rows of smaller cells are connected in series to form a photovoltaic string 912.

In the example shown in FIG. 9, photovoltaic panel 900 can include three U-shaped strings with each string including 72 smaller cells. The V_{oc} and I_{sc} of the string are 72V_{oc}_{_}_{cell} and I_{sc}_{_}_{cell}/3, respectively; and the V_{oc} and I_{sc} of the panel are 72V_{oc}_{_}_{cell}, and I_{sc}_{_}_{cell}, respectively. Such panel level V_{oc} and I_{sc} are similar to those of a conventional photovoltaic panel of the same size with all its 72 cells connected in series, making it possible to adopt the same circuit equipment developed for the conventional panels.

Furthermore, the total internal resistance of panel 900 is significantly reduced. Assume that the internal resistance of a conventional cell is R_{cell}. The internal resistance of a smaller cell is Rₛₘₐₗₗ_{_}_{cell}=R_{cell}/3. In a conventional panel with 72 conventional cells connected in series, the total internal resistance is 72 R_{cell}. In panel 900 as illustrated in FIG. 9, each string has a total internal resistance R_{string}=72 Rₛₘₐₗₗ_{_}_{cell}=24 R_{cell}. Since panel 900 has 3 U-shaped strings connected in parallel, the total internal resistance for panel 900 is R_{string}/3=8 R_{cell}, which is 1/9 of the total internal resistance of a conventional panel. As a result, the amount of power that can be extracted to external load can be significantly increased.

As one can see, the greater m is, the lower the total internal resistance of the panel can be, and the more power one can extract from the panel. However, a tradeoff is that as m increases, the number of connections required to inter-connect the strings also increases, which can increase the amount of contact resistance. Also, the greater m is, the more strips a single cell may need to be divided into, which may increase the associated production cost and decrease overall reliability due to the larger number of strips used in a single panel.

Another consideration in determining m is the contact resistance between the electrode and the photovoltaic structure on which the electrode is formed. The greater this contact resistance is, the greater m might need to be to reduce effectively the panel's overall internal resistance. Hence, for a particular type of electrode, different values of m might be needed to attain sufficient benefit in reduced total panel internal resistance to offset the increased production cost and reduced reliability. For example, conventional silver-paste or aluminum based electrode may require m to be greater than 4, because the process of screen printing and annealing silver paste on a cell does not produce ideal resistance between the electrode and underlying photovoltaic structure.

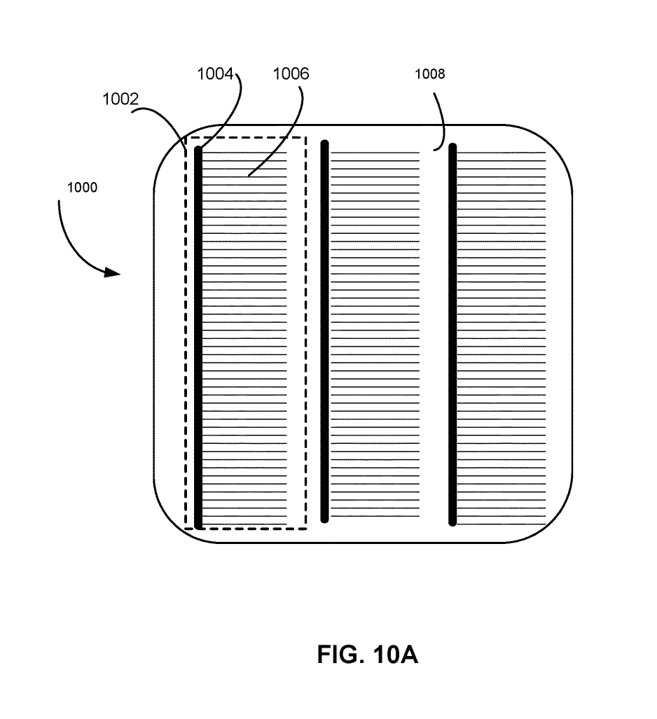

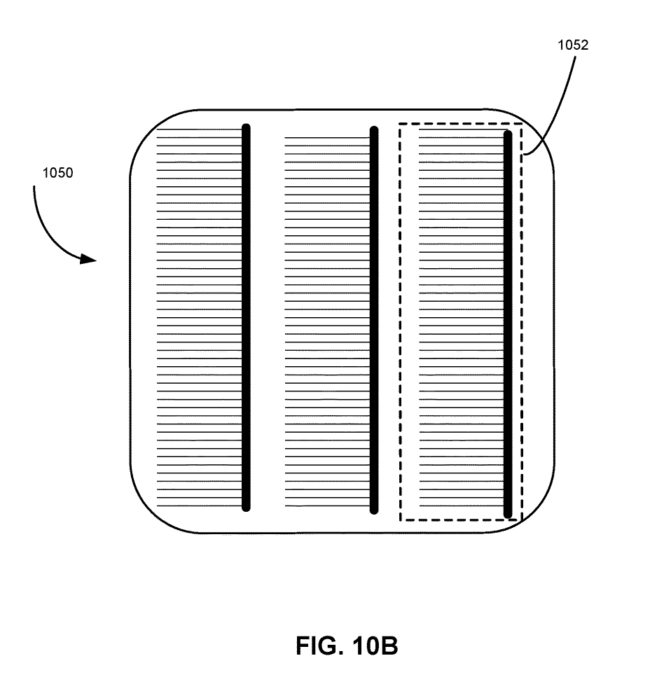

FIG. 10A shows an exemplary grid pattern on a photovoltaic structure, according to one embodiment of the present invention. In the example shown in FIG. 10A, grid 1000 can include three sub-grids, such as sub-grid 1002. This three sub-grid configuration allows the photovoltaic structure to be divided into three strips. To enable cascading, each sub-grid can have an edge busbar. In the example shown in FIG. 10A, each sub-grid can include an edge busbar (“edge” here refers to the edge of a respective strip) along the longer edge of the corresponding strip and a plurality of finger lines running substantially along the shorter edge of the strip. For example, sub-grid 1002 can include edge busbar 1004, and a plurality of finger lines, such as finger line 1006. To facilitate a subsequent scribe-and-cleave process, a predefined blank space (i.e., space not covered by electrodes) can be placed between the adjacent sub-grids. In some embodiments, the width of the blank space, such as blank space 1008, can be between 0.1 mm and 5 mm, preferably between 0.5 mm and 2 mm. There is a tradeoff between a wider space that leads to more tolerant scribing operation and a narrower space that leads to more effective current collection. In a further embodiment, the width of such a blank space can be approximately 1 mm.

FIG. 10B shows an exemplary grid pattern on the back surface of a photovoltaic structure, according to one embodiment of the invention. In the example shown in FIG. 10B, back grid 1050 can include three sub-grids, such as sub-grid 1052. To enable cascaded and bifacial operation, the back sub-grid can correspond to the front-side sub-grid. More specifically, the back edge busbar can be located at an opposite edge with respect to the corresponding front-side edge busbar. In the examples shown in FIGS. 10A and 10B, the front and back sub-grids have similar patterns except that the front and back edge busbars are located adjacent to opposite edges of the strip. In addition, locations of the blank spaces in back metallic grid 1008 can correspond to locations of the blank spaces in front metallic grid 1000, such that the grid lines do not interfere with the subsequent scribe-and-cleave process. In practice, the finger line patterns on the front- and back-side of the photovoltaic structure may be the same or different.

### Bifacial Photovoltaic Panels Based on Angled Cascaded Strips

Current photovoltaic panels are generally rectangular shaped which results in wasted installation space that is not a perfect square or rectangle. In order to use the installation space more efficiently, custom photovoltaic panels with various geometrical shapes can be used. To produce such photovoltaic panels, multiple photovoltaic cells with a single busbar (either at the cell center or the cell edge) per surface can be assembled to form a photovoltaic panel via a typical panel fabrication process with minor modifications. More specifically, the serial connection between adjacent strips is achieved by partially overlapping the adjacent photovoltaic strips with an offset, thus resulting in the direct contact of a portion of the corresponding edge busbars.

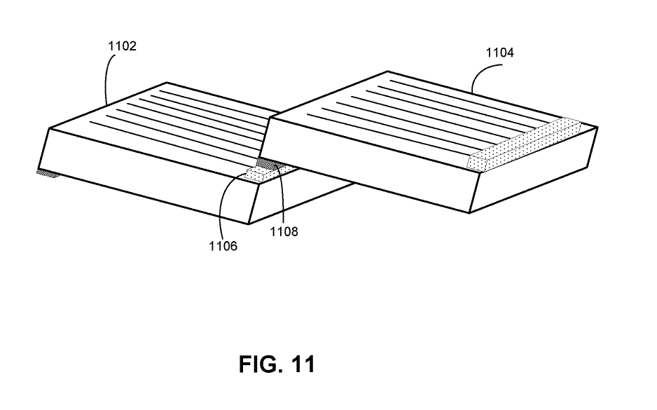

FIG. 11 shows the serial connection between two adjacent smaller cells with a single edge busbar per surface, in accordance with an embodiment of the present invention. In FIG. 11, photovoltaic cell 1102 and photovoltaic cell 1104 are coupled to each other via edge busbar 1106 located at the top surface of strip 1102 and edge busbar 1108 located the bottom surface of cell 1304. Although edge busbar 1106 and 1108 are in direct contact, these busbars are not aligned perfectly straight. As a result of this modification, photovoltaic cells 1102 and 1104 are only partially overlapped and can form an angled cascaded strip.

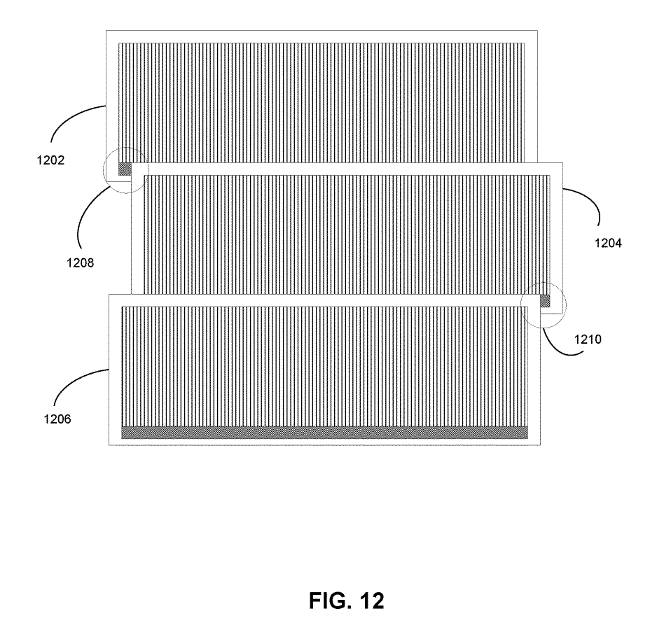

FIG. 12 shows the top view of the serial connection with an offset between three adjacent smaller cells with a single edge busbar on each side of the cell, according to an embodiment. In FIG. 12, strip 1206 partially overlaps adjacent strip 1204, which also partially overlaps (on its opposite end) strip 1202. As can be seen, because of the serial connection between these photovoltaic strips has an offset, at least a portion of these serially connected photovoltaic strips are not being overlapped. For example, regions 1208 and 1210 each show a portion of busbars from photovoltaic strips 1202 and 1204 that are not being overlapped, thereby forming a serial connection with an offset.

Such an angled string of strips forms a pattern that is similar to roof shingles. Note that, in some embodiments, the three photovoltaic strips shown in FIG. 12 are in fact parts of a standard 6-inch square solar cell, with each strip having a dimension of 2 inches by 6 inches. Compared with an undivided 6-inch solar cell, the partially overlapped strips provide roughly the same photo-generation area but can lead to less power being consumed by the series resistance due to the reduced current. The overlapping should be kept to a minimum to minimize shading caused by the overlapping. In some embodiments, the single busbars (both at the top and the bottom surface) are placed at the very edge of the photovoltaic strip (as shown in FIG. 12), thus minimizing the overlapping.

In other embodiments, the same shingle pattern can extend along all strips in a row so that an appropriate offset value for the connections between the strips can be selected to obtain strings with different angles. In some embodiments, as shown in FIG. 12, the angled cascaded strip can include both positive and negative offset values which results in forming a photovoltaic panel with a curved and/or irregular geometrical shape.

Note that having different offset values selected to obtain strings with different angles can adversely affect the amount of current that pass through the string, which in turn affects the efficiency of the photovoltaic panel. In some embodiments, the offset value may be large enough causing current bottlenecks at the overlapped areas of strips within the angled string. In order to achieve a balance between current generated by the photovoltaic panel and offset value(s) of strips, a minimum contact area between overlapped edge busbars of the strips can be determined. For example, wider edge busbars may be used if an offset value is greater than average for at least a portion of an angled string so that a minimum contact area between edge busbars of the strips can be maintained. As another example, if an offset value is smaller than average for at least a portion of an angled string, only a narrower busbar can be used or only a portion of the busbar's width may be overlapped so that the minimum contact area between the overlapped edge busbars is maintained.

As mentioned previously, because the serial connection between photovoltaic strips has an offset, at least a portion of these serially connected photovoltaic strips (e.g., regions 1208 and 1210 shown in FIG. 12) are not overlapped. In some embodiments, these portions of the strips that are not overlapped can be measured prior to fabrication of the metallic grid of these strips in order to calculate the size and position of the overlapped portion(s) of these serially connected photovoltaic strips for each specific offset value. By only fabricating the overlapped portion of edge busbars within the angled string, fabrication process can be made easier by simplifying the alignment process of the overlapped portion of edge busbars within the angled string. In addition, elimination of the busbar portions that are not overlapped leads to reduced production cost by using less fabrication material and more efficient photovoltaic panel by minimizing shading loss from portions of edge busbars that are not overlapped.

Although fabricating only the overlapped portions of edge busbars provide a simpler manufacturing process and more effective photovoltaic panels with smaller shading loss, the smaller (i.e., overlapped portion of) busbar may not collect all the generated current within each strip. As shown in FIG. 12, regions 1208 and 1210 are responsible for current collection of a portion of each strip, and eliminating these regions would effectively make the collected current from each strip smaller. Therefore, in order to maximize the current being collected from this configuration, different metallization designs can be used to include all current being generated in the total collected current from the angled string. Hence, a photovoltaic panel that is made with this specific configuration can be more efficient.

In some embodiments, a modified busbar and/or different finger line patterns may be used to cover areas near overlapped regions. For example, a combination of regular shaped finger lines, slanted finger lines, and curved finger lines can be used in different configurations to draw almost all the current generated by each strip of the angled string. Details, including fabrication designs and methods for modified metallic grid can be found in U.S. patent application Ser. No. 14/985,223 (Attorney Docket No. P128-1NUS), entitled “ADVANCED DESIGNOF METALLIC GRID IN PHOTOVOLTAIC STRUCTURE,” by inventors Anand J. Reddy, and Jiunn Benjamin Heng, filed 30 Dec. 2015, the disclosure of which is incorporated herein by reference in its entirety herein.

To ensure that photovoltaic strip in two adjacent rows are connected in series, the two adjacent rows need to have opposite shingle patterns, such as right-side on top for one row and left-side on top for the adjacent row. Moreover, a metal tab can be used to serially connect the end strips at the two adjacent rows. Note that although the examples above illustrate adjacent solar cells being physically coupled with direct contact in a “shingling” configuration, in some embodiments of the present invention the adjacent solar cells can also be coupled electrically in series using conductive materials without being in direct contact with one another.

In some embodiments, adjacent strips may be bonded together via edge busbars having an offset while forming the photovoltaic panel. Such bonding can be important to ensure that the electrical connections are well maintained when the photovoltaic panel is put into service. One option for bonding the metallic busbars can include soldering. For example, the surface of the edge busbars may be coated with a thin layer of Sn. During a subsequent lamination process, heat and pressure can be applied to cure sealant material between photovoltaic structures and the covers. The same heat and pressure can also solder together the edge busbars that are in contact. However, the rigid bonding between the soldered contacts may lead to cracking of the thin strips especially when partially overlapped. Moreover, when in service photovoltaic panels often experience many temperature cycles, and the thermal mismatch between the metal and the semiconductor may create structural stress that can lead to fracturing.

To reduce the thermal or mechanical stress, it can be preferable to use a bonding mechanism that is sufficiently flexible and can withstand many temperature cycles. One way to do so is to bond the strips using flexible adhesive that is electrically conductive. For example, adhesive (or paste) can be applied on the surface of top edge busbar of a first strip, and the bottom edge busbar of the second strip can be bonded to the top edge busbar by the adhesive, which can be cured at an elevated temperature. Different types of conductive adhesive or paste can be used to bond the busbars.

In one embodiment, the conductive paste can include a conductive metallic core surrounded by a resin. When the paste is applied to a busbar, the metallic core establishes an electrical connection with the busbar while the resin that surrounds the metallic core functions as an adhesive. In another embodiment, the conductive adhesive may be in the form of a resin that includes a number of suspended conductive particles, such as Ag or Cu particles. The conductive particles may be coated with a protective layer. When the paste is thermally cured, the protective layer can evaporate to enable electrical conductivity between the conductive particles suspended inside the resin.

In an automated panel production line, before the strips are edge stacked to form an angled cascaded string, conductive paste needs to be applied on the surface of the busbars of each strip. In some embodiments, the conductive paste can be applied before a photovoltaic structure of a standard size is divided into multiple strips. In further embodiments, the conductive paste can be applied after the photovoltaic structure is scribed but before the photovoltaic structure is cleaved into strips. Applying the conductive paste prior to the photovoltaic structure being cleaved into multiple strips simplifies the aligning process required during the paste application. On the other hand, applying the conductive paste after the laser scribing process prevents possible curing of the paste by the laser beams. More details on bonding the edge busbars while forming photovoltaic strings are provided in U.S. patent application Ser. No. 14/857,653 (Attorney Docket No. P119-1NUS), entitled “PHOTOVOLTAIC CELLS WITH ELECTRODES TO HOUSE CONDUCTIVE PASTE,” by inventor Anand J. Reddy, filed Sep. 17, 2015, the disclosure of which is incorporated herein by reference in its entirety.

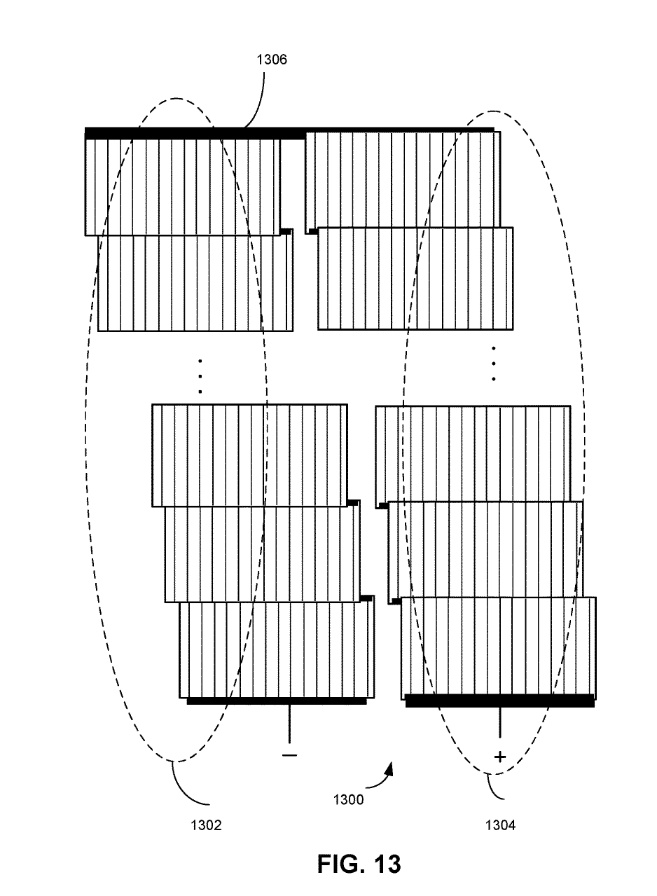

FIG. 13 shows the top view of an exemplary angled photovoltaic cell string that includes two rows of strips, in accordance with an embodiment of the present invention. In FIG. 13, string 1300 includes two rows of photovoltaic strips, top row 1302 and bottom row 1304. Each row includes a plurality of strips arranged with an offset in a shingled pattern. The serial connection is made by the partially overlapped edge busbars. As a result, when viewing from the top, only a small portion of each busbar can be seen on each photovoltaic strip. In FIG. 13, at the right end of the rows, metal tab 1306 couples together the top edge busbar of the end strip of row 1302 to the bottom edge busbar of the end strip of row 1304. At the left end of the rows, lead wires can be soldered onto the top and bottom edge busbars of the end photovoltaic strips, forming the output electrode of angled string 1300 to enable electrical connections between string 1300 and other strings to form photovoltaic panels with various geometrical shapes.

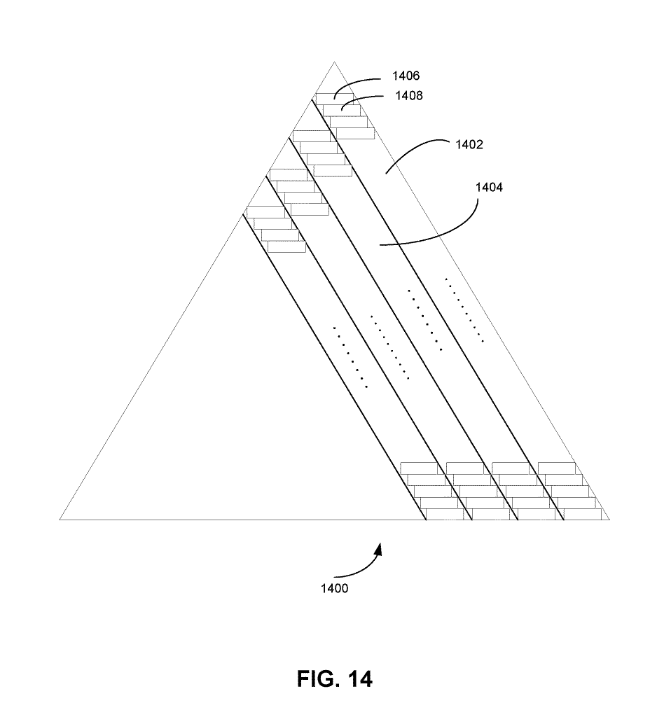

FIG. 14 shows a top view of exemplary photovoltaic panel 1400 in shape of a triangle that includes a plurality of angled strings, in accordance with an embodiment of the present invention. As shown in Fig.14, triangular shaped photovoltaic panel 1400 can be formed using multiple angled strings connected serially or in parallel. For example in FIG. 14, strings 1402 and 1404 can be connected serially or in parallel using metal tabs, in accordance to some embodiments. Each string (e.g., string 1402) can include a row of photovoltaic strips arranged with an offset in a shingled pattern. Each photovoltaic strip (e.g., cell 1406) is in a serial connection with an adjacent photovoltaic cell (e.g., cell 1408) by partially overlapped edge busbars.

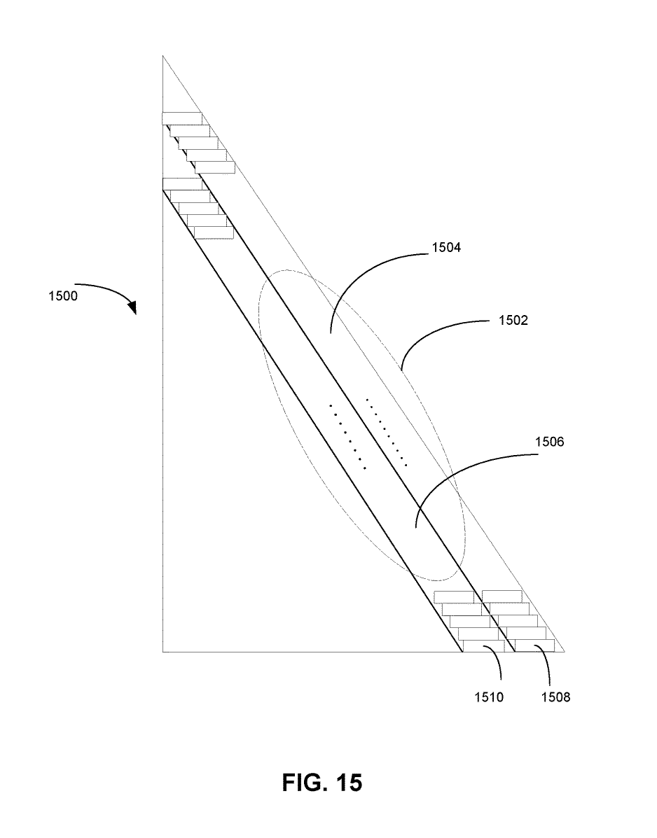

In some instances, it would be desirable to have a photovoltaic panel in shape of a right triangle for better integration with the conventional rectangular shaped panels. FIG. 15 shows a top view of exemplary photovoltaic panel 1500 in shape of a right triangle that includes a plurality of photovoltaic cells connected in series with an offset each having a single busbar on a surface, in accordance with an embodiment of the present invention. As shown in FIG. 15, triangular shaped photovoltaic panel 1500 can be formed using multiple angled strings connected serially. For example, angled string 1502 can be connected in parallel to its adjacent angled string, which in turn will be connected in parallel to its adjacent angled string. Angled string 1502 can include two rows of stips, right row 1502 and left row 1504. Each row includes a plurality of photovoltaic strips arranged with an offset in a shingled pattern. The serial connections between the photovoltaic strips are made by the partially overlapped edge busbars. In FIG. 15, at the bottom end of the rows, a metal tab can couple together the top edge busbar of photovoltaic strip 1508 to the bottom edge busbar of photovoltaic strip 1510.

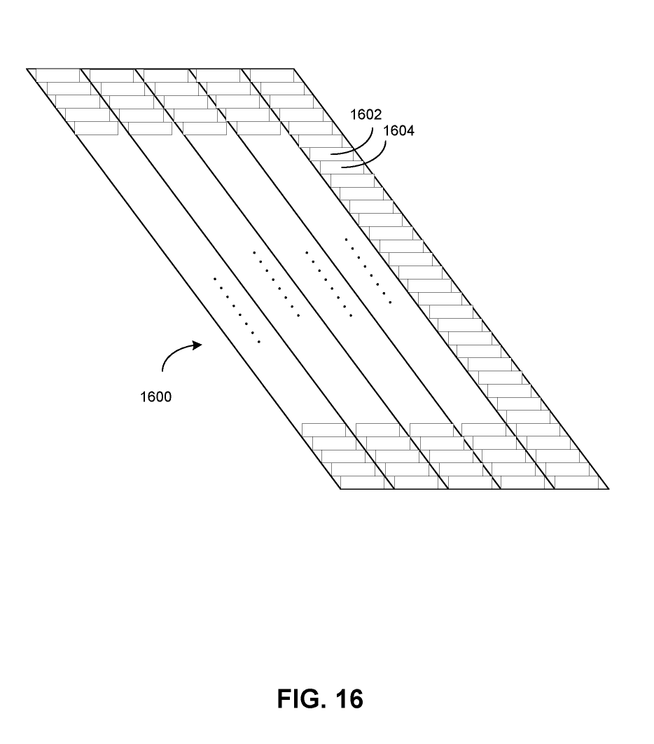

In addition to triangle shaped photovoltaic panels, other geometric shapes can be formed using the angled cascaded photovoltaic strips. In an embodiment, as shown in FIG. 16, photovoltaic panel 1600 can be in shape of a parallelogram. Similar to other various geometric shaped panels, the parallelogram shaped photovoltaic panel 1600 is formed by arranging photovoltaic strips (e.g., photovoltaic cells 1602 and 1604) into angled strings using a shingled pattern with an offset, and connecting the angled strings to create the parallelogram shaped photovoltaic panel 1600. Note that these panels can be especially useful in covering system installation areas that cannot be perfectly covered with conventional rectangular shaped and/or triangle shaped photovoltaic panels. Moreover, Parallelogram shaped photovoltaic panel can also be very effective in utilizing the installation areas since it virtually does not leave any unused space around its corners.

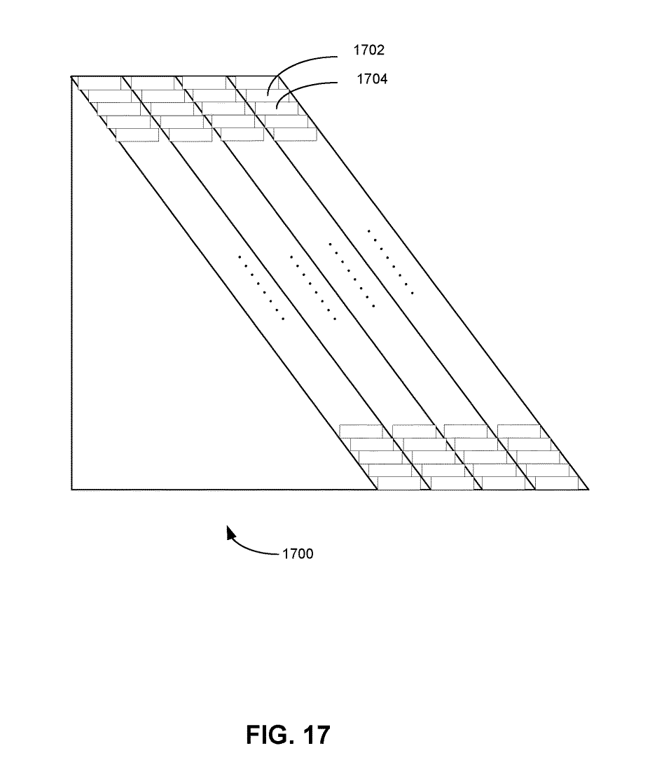

FIG. 17 shows an exemplary photovoltaic panel with another geometrical shape, in accordance to an embodiment of the present invention. The trapezoid shaped photovoltaic panel 1700 can be formed by connecting multiple angled strips in series or parallel, where each angled strip includes multiple photovoltaic cells (e.g., photovoltaic cells 1702 and 1704) with an offset. Trapezoid shaped photovoltaic panel can be used to provide a more aesthetically pleasing solar system and superior integration with conventional rectangular-shaped photovoltaic panels since length of each line segment of the trapezoid can be optimized for proper fitment for almost all kinds of installation areas.

In some embodiments, right-angled trapezoid shaped photovoltaic panel 1700 can be formed by dividing the right-angled trapezoid shape into a rectangle and right-angled triangle. The regular shingling pattern can be used to form the conventional rectangular portion of photovoltaic panel 1700 while the right-angled triangle portion is formed using the shingling pattern to connect the photovoltaic cells (e.g., photovoltaic cells 1702 and 1704) with an offset.

### Exemplary Fabrication Method I

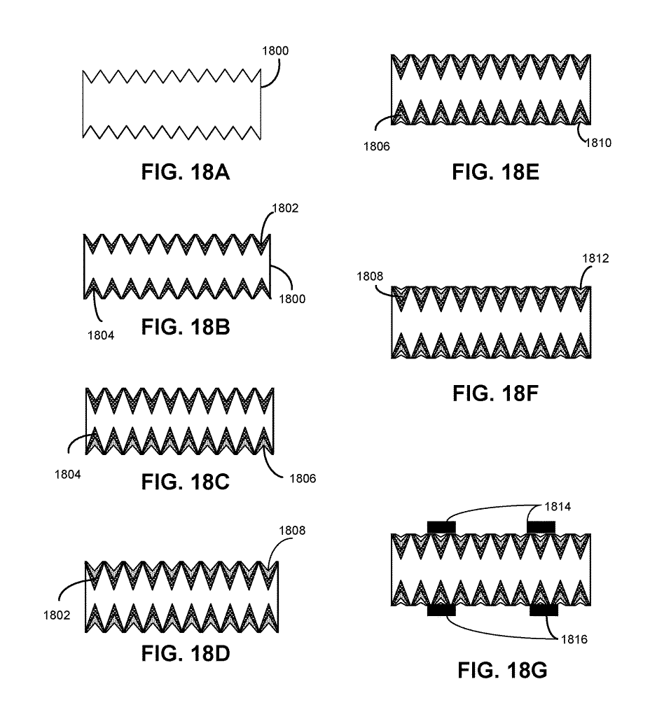

FIGS. 18A-G show an exemplary process of fabricating a photovoltaic structure, according to an embodiment of the present invention.

As shown in FIG. 18A, a substrate 1800 is prepared. In one embodiment, substrate 1800 can be a crystalline-Si (c-Si) wafer. In a further embodiment, preparing c-Si substrate 1800 can include saw damage etch, which removes the damaged outer layer of Si, and surface texturing. The c-Si substrate 1800 can be lightly doped with either n-type or p-type dopants. In one embodiment, c-Si substrate 1800 can be lightly doped with p-type dopants. Note that in addition to c-Si, other materials (e.g., metallurgical-Si) can also be used to form substrate 1800.

As shown in FIG. 18B, a doped emitter layer 1802 is formed on top of c-Si substrate 1800. Depending on the doping type of c-Si substrate 1800, emitter layer 1802 can be either n-type doped or p-type doped. In one embodiment, emitter layer 1802 is doped with n-type dopant. In a further embodiment, emitter layer 1802 is formed by diffusing phosphorous. Note that if phosphorus diffusion is used for forming emitter layer 1802, phosphosilicate glass (PSG) etch and edge isolation can be used. Other methods are also possible to form emitter layer 1802. For example, one can first form a poly Si layer on top of substrate 1800, and then diffuse dopants into the poly Si layer. The dopants can include either phosphorus or boron. Moreover, emitter layer 1802 can also be formed by depositing a doped amorphous Si (a-Si) layer on top of substrate 1800.

As shown in FIG. 18C, an anti-reflection layer 1804 is formed on top of emitter layer 1802. In one embodiment, anti-reflection layer 1804 includes, but not limited to: silicon nitride (SiNₓ), silicon oxide (SiOₓ), titanium oxide (TiOₓ), aluminum oxide (Al₂O₃), and their combinations. In one embodiment, anti-reflection layer 1804 can include a layer of a transparent conducting oxide (TCO) material, such as indium tin oxide (ITO), aluminum zinc oxide (AZO), gallium zinc oxide (GZO), tungsten doped indium oxide (IWO), and their combinations.

As shown in FIG. 18D, back-side electrode 1806 is formed on the back side of Si substrate 1800. In one embodiment, forming back-side electrode 1806 includes printing a full Al layer and subsequent alloying through firing. In one embodiment, forming back-side electrode 1806 can include printing an Ag/Al grid and subsequent furnace firing. In a further embodiment, forming back-side electrode 1806 can include electroplating the printed Ag/Al grid using one or more of a Cu layer, an Ag layer, and a Sn layer.

As shown in FIG. 18E, a number of contact windows, including windows 1808 and 1810, can be formed in anti-reflection layer 1804. In one embodiment, heavily doped regions, such as regions 1812 and 1814 can be formed in emitter layer 1802, directly beneath contact windows 1808 and 1810, respectively. In a further embodiment, contact windows 1808 and 1810 and heavily doped regions 1812 and 1814 are formed by spraying phosphorous on anti-reflection layer 1804, followed by a laser-groove local-diffusion process. Note that the operation shown in FIG. 18E is optional, and can be performed when anti-reflection layer 1804 is electrically insulating. If anti-reflection layer 1804 is electrically conducting (e.g., when anti-reflection layer 1804 is formed using TCO materials), there is no need to form the contact windows.

As shown in FIG. 18F, a metal adhesive layer 1816 is formed on anti-reflection layer 1804. In one embodiment, materials used to form adhesive layer 1816 include, but are not limited to: Ti, titanium nitride (TiNₓ₎, titanium tungsten (TiWₓ₎, titanium silicide (TiSiₓ), titanium silicon nitride (TiSiN), Ta, tantalum nitride (TaNₓ), tantalum silicon nitride (TaSiNₓ), nickel vanadium (NiV), tungsten nitride (WNₓ), Cu, Al, Co, W, Cr, Mo, Ni, and their combinations. In a further embodiment, metal adhesive layer 1816 is formed using a physical vapor deposition (PVD) technique, such as sputtering or evaporation. The thickness of adhesive layer 1816 can range from a few nanometers up to 100 nm. Note that Ti and its alloys tend to form very good adhesion with Si material, and they can form good ohmic contact with heavily doped regions 1812 and 1814. Forming metal adhesive layer 1814 on top of anti-reflection layer 1804 prior to the electroplating process can provide better adhesion to anti-reflection layer 1804 of the subsequently formed layers.

As shown in FIG. 18G, a metal seed layer 1818 can be formed on adhesive layer 1816. Metal seed layer 1818 can include Cu or Ag. The thickness of metal seed layer 1818 can be between 12 nm and 500 nm. In one embodiment, metal seed layer 1818 has a thickness of 100 nm. Like metal adhesive layer 1816, metal seed layer 1818 can be formed using a PVD technique. In one embodiment, the metal used to form metal seed layer 1818 is the same metal that used to form the first layer of the electroplated metal. The metal seed layer provides better adhesion of the subsequently plated metal layer. For example, Cu plated on Cu often has better adhesion than Cu plated on to other materials.

As shown in FIG. 18H, a patterned masking layer 1820 is deposited on top of metal seed layer 1818. The openings of masking layer 1820, such as openings 1822 and 1824, correspond to the locations of contact windows 1808 and 1810, and thus are located above heavily doped regions 1812 and 1814. Note that openings 1822 and 1824 are slightly larger than contact windows 1808 and 1810. Masking layer 1820 can include a patterned photoresist layer, which can be formed using a photolithography technique. In one embodiment, the photoresist layer is formed by screen-printing photoresist on top of the wafer. The photoresist can then be cured. A mask can be laid on the photoresist, and the wafer is exposed to UV light. After the UV exposure, the mask is removed, and the photoresist is developed in a photoresist developer. Openings 1822 and 1824 are formed after developing. The photoresist can also be applied by spraying, dip coating, or curtain coating. Dry film photoresist can also be used. Alternatively, masking layer 1820 can include a layer of patterned silicon oxide (SiO₂). In one embodiment, masking layer 1820 is formed by first depositing a layer of SiO₂ using a low-temperature plasma-enhanced chemical-vapor-deposition (PECVD) technique. In a further embodiment, masking layer 1820 can be formed by dip-coating the front surface of the wafer using silica slurry, followed by screen-printing an etchant that includes hydrofluoric acid or fluorides. Other masking materials are also possible, as long as the masking material is electrically insulating.

Note that masking layer 1820 defines the pattern of the front metallic grid because, during the subsequent electroplating, metal materials can only be deposited on regions above the openings, such as openings 1822 and 1824, defined by masking layer 1820.

As shown in FIG. 18I, one or more layers of metal are deposited at the openings of masking layer 1820 to form a front-side metallic grid 1826. Front-side metallic grid 1826 can be formed using an electroplating technique, which can include electrodeposition, light-induced plating, and/or electroless deposition. In one embodiment, metal seed layer 1818 and/or adhesive layer 1816 are coupled to the cathode of the plating power supply, which can be a direct current (DC) power supply, via an electrode. Metal seed layer 1818 and masking layer 1820, which includes the openings, are submerged in an electrolyte solution which permits the flow of electricity. Note that, because masking layer 1820 is electrically insulating, metals will be selectively deposited into the openings, thus, forming a metallic grid with a pattern corresponding to the one defined by those openings. Depending on the material forming metal seed layer 1818, front-side metallic grid 1826 can be formed using Cu or Ag. For example, if metal seed layer 1818 is formed using Cu, front-side metallic grid 1826 is also formed using Cu. In addition, front-side metallic grid 1826 can include a multilayer structure, such as a Cu/Sn bi-layer structure, or a Cu/Ag bi-layer structure. The Sn or Ag top layer is deposited to assist a subsequent soldering process. When depositing Cu, a Cu plate is used at the anode, and the photovoltaic structure is submerged in the electrolyte suitable for Cu plating. The current used for Cu plating is between 0.1 ampere and 2 amperes for a wafer with a dimension of 125 mm×125 mm, and the thickness of the Cu layer is approximately tens of microns. In one embodiment, the thickness of the electroplated metal layer is between 30 μm and 50 μm.

As shown in FIG. 18J, masking layer 1820 is removed.

As shown in FIG. 18K, portions of adhesive layer 1816 and metal seed layer 1818 that are originally covered by masking layer 1820 are etched away, leaving only the portions that are beneath front-side metallic grid 1826. In one embodiment, wet chemical etching process is used. Note that, because front-side metallic grid 1826 is much thicker (by several magnitudes) than adhesive layer 1816 and metal seed layer 1818, the etching has a negligible effect on front-side metallic grid 1826. In one embodiment, the thickness of the resulting metallic grid can range from 30 μm to 50 μm. The width of the finger strips can be between 10 μm to 200 μm, and the width of the busbars can be between 0.5 to 2 mm. Moreover, the spacing between the finger strips can be between 2 mm and 3 mm.

During fabrication, after the formation of the metal adhesive layer and the seed metal layer, it is also possible to form a patterned masking layer that covers areas that correspond to the locations of contact windows and the heavily doped regions, and etch away portions of the metal adhesive layer and the metal seed layer that are not covered by the patterned masking layer. In one embodiment, the leftover portions of the metal adhesive layer and the metal seed layer form a pattern that is similar to the ones shown in FIGS. 10 A-B. Once the patterned masking layer is removed, one or more layers of metals can be electroplated to the surface of the photovoltaic structure. On the photovoltaic structure surface, only the locations of the leftover portions of the metal seed layer are electrically conductive, a plating process can selectively deposit metals on top of the leftover portions of metal seed layer.

In the example shown in FIG. 18, the back-side electrode is formed using a conventional printing technique as shown in FIG. 18D. In practice, the back-side electrode can also be formed by electroplating one or more metal layers on the backside of the photovoltaic structure. In one embodiment, the back-side electrode can be formed, which include forming a metal adhesive layer, a metal seed layer, and a patterned masking layer on the backside of the substrate. Note that the patterned masking layer on the backside defines the pattern of the back-side metallic grid.

### Exemplary Fabrication Method II

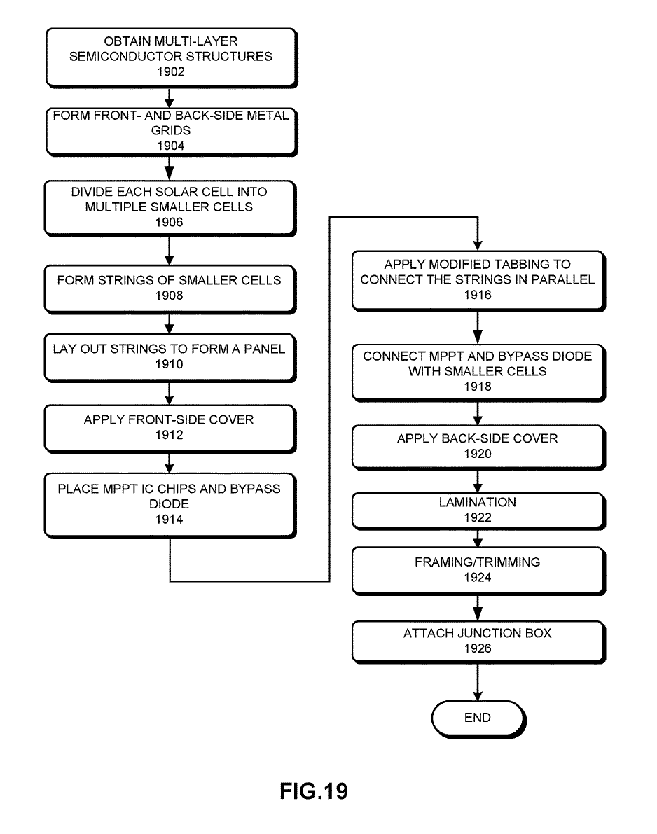

FIG. 19 shows another exemplary process of fabricating a back junction photovoltaic structure with tunneling oxide, according to an embodiment of the present invention.

In operation 19A, a substrate 1900 is prepared. In one embodiment, either n- or p-type doped high-quality solar-grade silicon (SG-Si) wafers can be used to build the back junction photovoltaic cell. In one embodiment, an n-type doped SG-Si wafer is selected. The thickness of SG-Si substrate 1900 can range between 80 and 200 μm. In one embodiment, the thickness of SG-Si substrate 1900 ranges between 90 and 120 μm. The resistivity of SG-Si substrate 1900 can range between 1 Ohm-cm and 10 Ohm-cm. In one embodiment, SG-Si substrate 1900 has a resistivity between 1 Ohm-cm and 2 Ohm-cm. The preparation operation can include typical saw damage etching that removes approximately 10 μm of silicon and surface texturing. The surface texture can have various patterns, including but not limited to: hexagonal-pyramid, inverted pyramid, cylinder, cone, ring, and other irregular shapes. In one embodiment, the surface texturing operation can result in a random pyramid textured surface. Afterwards, SG-Si substrate 1900 goes through extensive surface cleaning.

In operation 19B, a thin layer of high-quality (with Dᵢₜ less than 1×10¹¹/cm²) dielectric material is deposited on the front and back surfaces of SG-Si substrate 1900 to form front and back passivation/tunneling layers 1902 and 1904, respectively. In one embodiment, only the back surface of SG-Si substrate 1900 is deposited with a thin layer of dielectric material. Various types of dielectric materials can be used to form the passivation/tunneling layers, including, but not limited to: silicon oxide (SiOₓ), hydrogenerated SiOₓ, silicon nitride (SiNₓ), hydrogenerated SiNₓ, aluminum oxide (AlOₓ), silicon oxynitride (SiON), and hydrogenerated SiON. In addition, various deposition techniques can be used to deposit the passivation/tunneling layers, including, but not limited to: thermal oxidation, atomic layer deposition, wet or steam oxidation, low-pressure radical oxidation, plasma-enhanced chemical-vapor deposition (PECVD), etc. The thickness of tunneling/passivation layers 1902 and 1904 can be between 1 and 50 angstroms. In one embodiment, the thickness of tunneling/passivation layers 1902 and 1904 is between 1 and 15 angstroms. Note that the well-controlled thickness of the tunneling/passivation layers can ensure good tunneling and passivation effects.

In operation 19C, a layer of hydrogenerated, graded-doping a-Si having a doping type opposite to that of substrate 1900 is deposited on the surface of back passivation/tunneling layer 1904 to form emitter layer 1906. As a result, emitter layer 1906 is situated on the backside of the photovoltaic cell facing away from the incident sunlight. Note that, if SG-Si substrate 1900 is n-type doped, then emitter layer 1906 is p-type doped, and vice versa. In one embodiment, emitter layer 1906 is p-type doped using boron as dopant. SG-Si substrate 1900, back pas sivation/tunneling layer 1904, and emitter layer 1906 form the hetero-tunneling back junction. The thickness of emitter layer 1906 can be between 1 and 20 nm. Note that an optimally doped (with doping concentration varying between 1×10¹⁵/cm³ and 5×10²⁰/cm³) and sufficiently thick (at least between 3 nm and 20 nm) emitter layer can be used to ensure a good ohmic contact and a large built-in potential. In one embodiment, the region within emitter layer 1906 that is adjacent to front passivation/tunneling layer 1902 has a lower doping concentration, and the region that is away from front passivation/tunneling layer 1902 has a higher doping concentration. The lower doping concentration can ensure minimum defect density at the interface between back passivation/tunneling layer 1904 and emitter layer 1906, and the higher concentration on the other side may prevent emitter layer depletion. The work function of emitter layer 1906 can be tuned to better match that of a subsequently deposited back transparent conductive oxide (TCO) layer to enable higher fill factor. In addition to a-Si, it is also possible to use other material, including but not limited to: one or more wide-bandgap semiconductor materials and polycrystalline Si, to form emitter layer 1906.

In operation 19D, a layer of hydrogenerated, graded-doping a-Si having a doping type same as that of substrate 1900 is deposited on the surface of front passivation/tunneling layers 1902 to form front surface field (FSF) layer 1908. Note that, if SG-Si substrate 1900 is n-type doped, then FSF layer 1908 is also n-type doped, and vise versa. In one embodiment, FSF layer 1908 is n-type doped using phosphorous as dopant. SG-Si substrate 1900, front passivation/tunneling layer 1902, and FSF layer 1908 form the front surface high-low homogenous junction that can effectively passivates the front surface. In one embodiment, the thickness of FSF layer 1908 can be between 1 and 30 nm. In one embodiment, the doping concentration of FSF layer 1908 varies from 1×10¹⁵/cm³ to 5×10²⁰/cm³. In addition to a-Si, it is also possible to use other material, including but not limited to: wide-bandgap semiconductor materials and polycrystalline Si, to form FSF layer 1908.

In operation 19E, a layer of TCO material is deposited on the surface of emitter layer 1906 to form a back-side conductive anti-reflection layer 1910, which ensures a good ohmic contact. Examples of TCO include, but are not limited to: indium-tin-oxide (ITO), indium oxide (InO), indium-zinc-oxide (IZO), tungsten-doped indium-oxide (IWO), tin-oxide (SnOₓ), aluminum doped zinc-oxide (ZnO:Al or AZO), Zn—In—O (ZIO), gallium doped zinc-oxide (ZnO:Ga), and other large bandgap transparent conducting oxide materials. The work function of back-side TCO layer 1910 can be tuned to better match that of emitter layer 1906.

In operation 19F, front-side TCO layer 1912 is formed on the surface of FSF layer 1908. Front-side TCO layer 1912 forms a good anti-reflection coating to allow maximum transmission of sunlight into the photovoltaic cell.

In operation 19G, front-side electrode 1914 and back-side electrode 1916 are formed on the surfaces of TCO layers 1912 and 1910, respectively. In one embodiment, front-side electrode 1914 and back-side electrode 1916 include Ag finger grids, which can be formed using various techniques, including, but not limited to: screen printing of Ag paste, inkjet or aerosol printing of Ag ink, and evaporation. In a further embodiment, front-side electrode 1914 and/or back-side electrode 1916 can include Cu grid formed using various techniques, including, but not limited to: electroless plating, electro plating, sputtering, and evaporation. Note that the electrodes on both sides can be formed using various patterns with variable width finger lines. In a further embodiment, the metallic grids of both sides may include exemplary patterns shown in FIGS. 10 A-B.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

The methods and processes described in the detailed description section can be embodied as code and/or data, which can be stored in a computer-readable storage medium as described above. When a computer system reads and executes the code and/or data stored on the computer-readable storage medium, the computer system can perform the methods and processes embodied as data structures and code and stored within the computer-readable storage medium.

The foregoing descriptions of embodiments of the invention have been presented for purposes of illustration and description only. They are not intended to be exhaustive or to limit the invention to the forms disclosed. Accordingly, many modifications and variations may be apparent to practitioners skilled in the art. Additionally, the above disclosure is not intended to limit the invention. The scope of the invention is defined by the appended claims.

1. A photovoltaic panel comprising:
a plurality of photovoltaic cells arranged into a plurality of subsets, at least one subsets having a number of photovoltaic cells arranged in a geometrical shape with two edges forming an oblique angle;
wherein a number of photovoltaic cells in each subset is sufficiently large such that an output voltage of the photovoltaic panel is substantially the same as an output voltage of a conventional photovoltaic panel with all of its substantially square shaped photovoltaic cells coupled in series.

2. The photovoltaic panel of claim 1, wherein photovoltaic cells in a respective subset are electrically coupled in series, and wherein the subsets of photovoltaic cells are electrically coupled in parallel.

3. The photovoltaic panel of claim 1, wherein a respective photovoltaic cell is substantially rectangular shaped.

4. The photovoltaic panel of claim 1, wherein the arranged geometrical shape is at least one of a triangle, parallelogram, and trapezoid.

5. The photovoltaic panel of claim 1, wherein at least a portion of the arranged geometrical shape is curved.

6. The photovoltaic panel of claim 1, wherein a respective photovoltaic cell is a double-sided tunneling heterojunction photovoltaic cell, which includes:
a base layer;
first and second quantum tunneling barrier (QTB) layers deposited on both surfaces of the base layer;
an amorphous silicon emitter layer; and
an amorphous silicon surface field layer;
wherein the photovoltaic cell can absorb light from both surfaces.

7. The photovoltaic panel of claim 1, wherein a respective photovoltaic cell comprises a first metal grid on a first side and a second metal grid on a second side, wherein the first metal grid comprises a first edge busbar located near an edge on the first side, and wherein the second metal grid comprises a second edge busbar located near an opposite edge on the second side of the photovoltaic cell.

8. The photovoltaic panel of claim 7, wherein the first metal grid and the second metal grid each comprises an electroplated Cu layer.

9. The photovoltaic panel of claim 7, wherein two adjacent photovoltaic cells in a subset are positioned such that a first edge busbar of one photovoltaic cell is in direct contact with a second busbar of the other photovoltaic cell, thereby facilitating a serial connection between the two adjacent photovoltaic cells and substantially eliminating uncovered space there between.

10. The photovoltaic panel of claim 7, wherein two adjacent photovoltaic cells in a subset are positioned with an offset such that a portion of a first edge busbar of one photovoltaic cell is in direct contact with a second busbar of the other photovoltaic cell, thereby arranging the two adjacent photovoltaic cells with an offset.

11. The photovoltaic panel of claim 1, wherein the photovoltaic cells in the respective subset are physically coupled.

12-20. (canceled)

21. A photovoltaic system, comprising:
one or more photovoltaic panels electrically coupled to each other, wherein a respective photovoltaic panel comprises a plurality of photovoltaic structures arranged into a plurality of subsets, and wherein photovoltaic structures within a respective subset are arranged in a geometrical shape with two edges forming an oblique angle.

22. The photovoltaic system of claim 21, wherein the photovoltaic structures within the subset are electrically coupled in series, and wherein the subsets of photovoltaic structures are electrically coupled in parallel.

23. The photovoltaic system of claim 21, wherein the geometrical shape includes a triangle, a parallelogram, or a trapezoid.

24. The photovoltaic system of claim 21, wherein a respective photovoltaic structure comprises:
a base layer;
first and second quantum tunneling barrier (QTB) layers deposited on both surfaces of the base layer;
an amorphous silicon emitter layer; and
an amorphous silicon surface field layer;
wherein the photovoltaic structure is configured to absorb light from both surfaces.

25. The photovoltaic system of claim 21, wherein a respective photovoltaic structure comprises a first metal grid on a first side and a second metal grid on a second side, wherein the first metal grid comprises a first edge busbar located near an edge on the first side, and wherein the second metal grid comprises a second edge busbar located near an opposite edge on the second side of the photovoltaic structure.

26. The photovoltaic system of claim 25, wherein the first metal grid and the second metal grid each comprises an electroplated Cu layer.

27. The photovoltaic system of claim 25, wherein two adjacent photovoltaic structures in a subset are positioned such that a first edge busbar of one photovoltaic structure is in direct contact with a second busbar of the other photovoltaic structure, thereby facilitating a serial connection between the two adjacent photovoltaic structure s and substantially eliminating uncovered space there between.

28. The photovoltaic system of claim 25, wherein two adjacent photovoltaic structures in a subset are positioned with an offset such that a portion of a first edge busbar of one photovoltaic structure is in direct contact with a second busbar of the other photovoltaic structure, thereby arranging the two adjacent photovoltaic structures with an offset.
